(19) United States
(12) Patent Application Publication
(10) Pub. No.: US 2011/0265856 A1
(43) Pub. Date: Nov. 3, 2011

(54) Monolithic thin-film photovoltaic device with enhanced output voltage

(75) Inventor: Boris Gilman, Mountain View, CA (US)

(73) Assignee: Alexander SHKOLNIK

(21) Appl. No.: 12/799,672

(22) Filed: Apr. 29, 2010

(51) Int. Cl. H01L 31/06

(52) U.S. Cl. 136/249

(57) ABSTRACT

A monolithic thin-film tandem solar cell wherein the enhanced output voltage as high as 100 V or higher can be achieved in a single monolithic device and wherein automatic current matching is achieved between the cells. The monolithic cell comprises a plurality of individual tandem solar cells arranged side-by-side in the longitudinal direction of the substrate. Each individual tandem solar cell consists of a pair of thin-film photovoltaic cells arranged side-by-side. The layers are arranged so that when one of the overlapped layers is a heavily doped P-layer, the other one, which is coplanar to this P-layer, is a heavily doped N-layer and so that overlapped P- and N-layers form an area of a tunnel junction through which the first thin-film photovoltaic cell and a second thin-film photovoltaic cell are electrically connected to each other in series.

### FIELD OF THE INVENTION

The present invention relates to solar energy conversion devices, in particular, to thin-film photovoltaic cells and modules. More specifically, the invention relates to a monolithic thin-film tandem solar cell with an enhanced output voltage and automatic current matching between the component cells. The enhanced output voltage of the device of the invention may be as high as 100 V or higher and can be achieved in a single monolithic device, i.e., without connecting in series a plurality of pre-manufactured solar cells.

### BACKGROUND OF THE INVENTION

At the present time thin-film solar cells (TFSCs) and panels represent one of the largest segments of the photovoltaic industry, mainly due to their low cost, possibility of using large flexible substrates, and improved thermal properties. The most popular materials for TFSCs include hydrogenated amorphous silicon (αSi:H), microcrystalline or nanocrystalline Si, CdTe/CdS, and CuInGaSe (CIGS) films. A general description of these TFSCs is given in Physics of Semiconductor Devices, Second Edition, by S. M. Sze, John Wiley and Sons, 1981, pp. 825-830.

An αSi:H-based TFSC is typically made in the form of a single αSi:H-layer that contains a PIN-structure or in the form of stacked αSi:H-layers wherein each layer consists of a PIN structure and wherein a connection between the layers is made through a Tunnel Junction (TJ). The latter design is commonly known as a tandem solar cell (TSC) or a multi-junction solar cell (MJSC). Underneath the αSi:H top layer, a TSC may also include layers of micro-crystalline or nano-crystalline Si. A tandem design is generally preferred as it exhibits a higher output voltage (Vₒᵤₜ) and a higher power conversion efficiency (PCE) compared to a single-layer cell. When a TSC made exclusively of αSi:H layers, the tandem design is used also to reduce an impact from the so-called Staebler-Wronsky (SW) effect. A detailed description of an αSi:H-based TSC is given in “Amorphous Silicon-Based Photovoltaics—from Earth to the “final Frontier” by Jeffrey Yang, et al., in: Solar Energy Materials & Solar Cells”, v.78, pp.597-612. It should be noted that all known TSCs are designed as “vertical” structures, wherein the top PV cell is formed on the surface of the bottom PV cell, i.e., on the light-receiving side of a TSC, and absorbs solar radiation of high photon energy (i.e., with shorter wavelengths), while the bottom PV cell (or cells, in case of more than two sub-cells of a TSC) is formed beneath the top PV cell and absorbs the radiation of the low photon energy (longer wavelength).

FIG. 1 schematically shows a general cross-section of a typical thin-film TSC made, e.g., of two αSi:H PV cells of a PIN structure as described above. TSC 100 is formed on a transparent common substrate 102 that is made, e.g., of glass or flexible plastic material and pre-coated with an anti-reflection (AR) film 104 (made, e.g., of index-matching layers of silicon oxide and silicon nitride) and a first transparent electrode 106 made, e.g., of a transparent conductive oxide (hereinafter referred to as TCO). The AR and TCO layers 104 and 106 are formed on the transparent substrate 102 prior to forming photo-active layers (which are described below) of the TSC. It should be noted that in order to enhance light absorption in a TSC, the transparent substrate 102 can be pre-textured (not shown).

The photo-active section 108 of the TSC 100 comprises two PV cells, specifically, a top cell 110 and a bottom cell 112 connected in series through a tunnel junction 114 (FIG. 1). In FIG. 1 and in subsequent drawings, the terms “top” and “bottom” refer to the direction of the incoming light, as shown by curved arrows L in FIG. 1.

Each PV cell has a PIN structure consisting of αSi:H layers described below. More specifically, the top PV cell 110 is formed on the surface of the TCO layer 106, while the bottom PV cell 112 is formed on the back surface of the top cell 110. PIN structures of both PV cells 110 and 112 include heavily doped P-layers (hereinafter referred to merely as “P-layers”) 116a, 116b, intrinsic I- layers 118a, 118b, and heavily doped N-layers (hereinafter referred to merely as N-layers) 120a, 120b, respectively. The tunnel junction 114 is formed between the N-layer 120a of the top PV cell 100 and the P-layer 116b of the bottom PV cell 112.

A bottom electrode 122 is formed on the back surface of the TSC 100, specifically, on the surface of the N-layer 120b of the bottom PV cell 112. The electrode 122 can be made of low- resistance highly reflective metals, e.g., Al, and covers most of the back surface of the TSC 100.

In operation mode of the conventional TSC 100, i.e., when solar rays L fall onto the transparent substrate 102, the TSC 100 shown in FIG. 1 typically develops an output voltage Vₒᵤₜ in the range of 1.5-1.8 V, and may have an overall PCE on the order of 10 to 14%. It should be noted that although the example of TSC shown in FIG. 1 has only two vertically arranged PV cells, a TSC with three vertically arranged PV cells is also known and can be used as an example of the prior art. The output voltage Vₒᵤₜ for a three junction TSC could reach values close to 2.5-2.8V. Although theoretically it can be assumed that a TSC may include more than three vertically arranged PV cells, in reality, however, such a structure cannot be realized since it would be almost impossible to form photo-active layers that could provide current matching between the cells and at the same time satisfy requirements of material compatibility.

Although the aforementioned TSC design has been proven to be efficient, it still has some challenges, which are the following:

1) Providing current matching conditions between the top and bottom cells. While the current matching problem is generally resolved by TSC manufacturers (see, e.g., U.S. Pat. No. 5,853,497 issued in 1998 to D. Lillington, et al., and U.S. Patent Application Publication No. 2009242018, published in 2009, inventors: A. S. Won, et al.), it is clear that the ideal matching is very difficult to obtain due to a number of factors that affect photo current generation in the TSC layers (see, e.g., Top-Cell Thickness as an Adjustable Parameter, by S. R. Kurtz, et al. in “Journal of Applied Physics”, 68 (4), pp. 1890 to 1895). More specifically, any particular TSC design needs a very thorough calculation and verification of thicknesses of the top and bottom photo-active layers as well as of other critical electrical parameters of the sub-layers because the layers are required to absorb approximately equal parts of solar radiation and to generate the same or nearly the same photo currents in both top and bottom cells. The current matching problem becomes increasingly difficult to resolve for a TSC with three or more vertically stacked PV cells. In addition to the above, optical and recombination properties of both front and back surfaces of the TSC also should be taken into account and this makes the current matching task even more complex.

2) Reducing a manufacturing cost associated with depositing multiple additional layers beneath the top cell and with the necessity of providing series connection to adjacent cells by large-area tunnel junctions. Achieving a high-quality large-area tunnel junction with low series resistance represents a problem in TSC production (see, e.g., Development of Highly Efficient αSi:H Tandem Thin Film Solar Cells on 5.7 m² Size Glass Substrate, by A. Kadam, et al., in: “23^{rd} European Photovoltaic Solar Energy Conference, 1-5 Sep. 2008, Valencia, Spain, pp. 2062-2064).

3) Providing thin-film material compatibility between the top cell and underlying cells, particularly when the number of cells in TSC is greater than two.

It should be also noted that although a TSC design generally provides Vₒᵤₜ higher than in a single-layer TFSC, typical values of Vₒᵤₜ do not exceed 1.6 to 1.8 V for a double-layer structure and 2.0 to 2.4 V for a triple-layer structure, respectively (see e.g. “Amorphous Silicon-Based Photovoltaics—from Earth to the “final Frontier” by Jeffrey Yang, et al., in: Solar Energy Materials & Solar Cells”, v.78, pp.597-612). While the above values of Vₒᵤₜ are commonly considered acceptable because they can provide a required output voltage of a Solar Module (SM) by connecting TSC cells in series, the SP design could be significantly simplified if a TSC cell could produce an elevated Vₒᵤₜ , e.g., 24V or above.

Attempts have been made to develop solar modules wherein individual cells are connected in series to obtain elevated Vₒᵤₜ and to simplify the SP design (see, e.g., U.S. Pat. No. 6,281,428 issued in 2001 to J. Chiu, et al., and International Patent Application Publication WO0205352, published in 2002, inventors: R. Oswald, et al.). The above technical solutions provide integrated series connection of individual solar cells that results in the enhanced Vₒᵤₜ.

U.S. Patent Application Publication No. 20090301543 (inventors: D. Reddy, et al.; published in 2009) discloses a thin film photovoltaic device with monolithic integration and backside metal contacts. Although the device of this application can be manufacture as a monolithic structure, neither this structure nor any other structure described above or known in the art discloses a monolithic thin-film tandem-type solar cell capable of producing a gigantic output voltage on the order of 100 V or more with simultaneous automatic current matching between the component cells.

### SUMMARY OF THE INVENTION

The present invention provides a novel and efficient monolithic thin-film solar cell (MTF-SC) comprising a plurality of individual TSCs arranged on a transparent common substrate in the longitudinal direction on the light-receiving side The invention allows generating a significantly enhanced output photo voltage Vₒᵤₜ whereby an MTF-SC can be used as a photovoltaic generator.

According to the present invention, the transparent common substrate comprises a glass plate or a flexible plastic material, such as vinyl, and a pre-coated anti-reflection (AR) index-matching film(s), such as silicon dioxide or silicon nitride. As commonly used in known PV devices, in order to reduce light reflection and improve light-trapping efficiency the substrate may be pre-textured. On the backside, which is opposite to the transparent common substrate, the device has a planar surface on which all contacts (electrodes) of the PV cells of individual TSCs and interconnection between the adjacent TSCs are formed. The described design eliminates light-shadowing features, such as metal contacts and lines, on the front surface of the MTF-SC, thereby allowing use of the maximum amount of the incoming radiation.

An individual TSC of the present device consists of two PV cells (referred to as “first PV cell” and “second PV cell”), each having a PIN structure formed on the common transparent substrate next to each other and connected in series through the tunnel junction, which is formed between a portion of the N-doped layer of the first PV cell, that extends into the second PV cell, and the P-doped layer of the second PV cell. The aforementioned first PV cell and second PV cell are isolated from each other by an insulating layer formed between the PV cells.

PIN structures of the aforementioned first and second PV cells have inverse sequences of doped sub-layers so that the PIN structure of the first PV cell of an individual TSC is arranged adjacent and coplanar to the NIP structure of the second PV cell, or vice versa.

According to one or more aspects of the present invention, individual TSCs of the MTF-SC are reliably separated and isolated from each other by narrow deep trenches formed vertically between all adjacent TSCs. The deep trenches are etched off through the entire TSC structures down to the transparent common substrate. According to one aspect of the present invention, the aforementioned deep trenches can be filled with an insulating material, such as silicon oxide, silicon nitride, or the like, which provides a reliable electrical isolation of the adjacent TSCs, as well as an insulation layer on the backside surface that is suitable for further interconnection of individual TSCs. The deep trenches and insulation described above are made by well known patterning processes, such as photo lithography, etching, and CVD deposition.

According to one aspect of the present invention, the TSCs are provided with metal electrodes formed on the P-doped layers of the first PV cells and with metal electrodes formed on the N-doped layers of the second PV cells. Furthermore, in order to generate an enhanced Vₒᵤₜ, the adjacent individual TSCs, in turn, are connected in series by metal links formed on the backside surface of the device over the insulating layers. The aforementioned metal link of each individual TSC connects the electrode formed on the N-doped layer of the second PV cell of this TSC to the electrode formed on the P-doped layer of the first PV cell of the adjacent TSC.

According to the present invention, dimensions of the first and second PV cells are chosen to make thicknesses of the photoactive intrinsic I-layers and cross-sectional areas of first and second PV cells equal or nearly equal to each other thus providing equal or nearly equal photo currents generated in the cells of each individual TSC. This ensures perfect current matching conditions in all individual TSCs. Furthermore, to reduce radiation and photo current losses in the trench region, the deep trenches are made as narrow as possible when compared to the areas of the PV cells.

As has been mentioned above, the individual TSCs of the MTF-SC are connected in series by metal links formed over the insulating layers. More specifically, each metal link directly contacts the electrode formed on the N-doped layer of the second PV cell of an individual TSC on one side and also directly contacts the electrode formed on the P-doped layer of the first PV cell of an adjacent TSC, thus connecting individual TSC in series. All contacts and metal line patterns are formed on the backside surface by means of the well known masking processes common to microelectronics.

### BRIEF DESCRIPTION OF THE DRAWINGS

FIG. 1 is a general cross-sectional view of a known thin-film tandem solar cell (TSC).

FIG. 2 is a schematic cross-sectional view of the device of the present invention comprising a plurality of individual TSCs connected in series.

FIG. 3 is a top view of the back side of the TIF-SC that consists of a plurality of individual TSCs.

FIG. 4 is an equivalent electrical circuit of the device of the invention.

FIG. 5 is a graph that compares output I-V characteristics of the device of the invention with a conventional thin-film tandem solar cell.

### DETAILED DESCRIPTION OF THE INVENTION

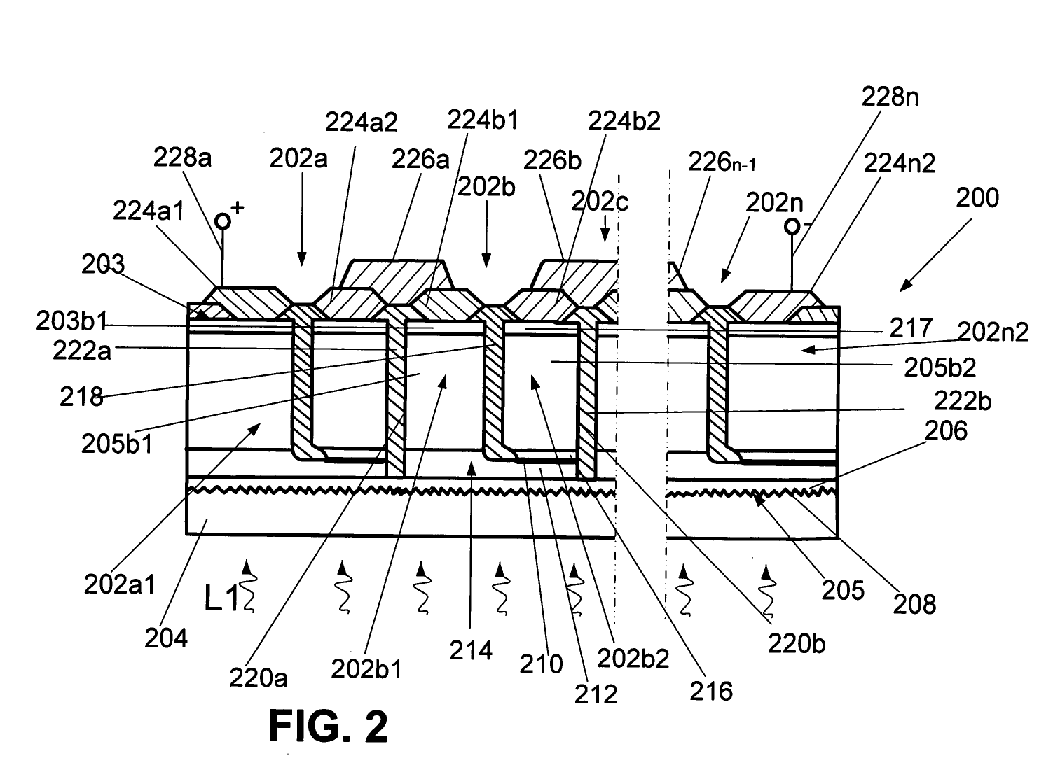

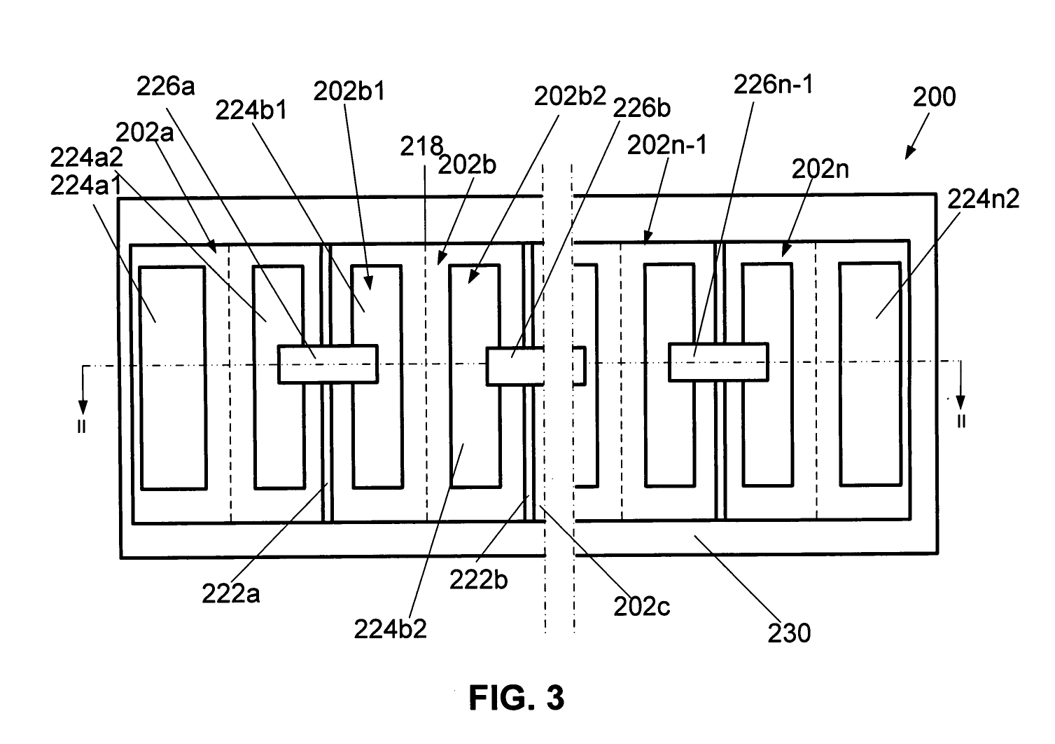

In general, the device of the invention comprises a novel and efficient monolithic thin-film solar cell (hereinafter referred to as MTF-SC) 200 shown in FIG. 2, which is a longitudinal sectional view of the device along line II-II of FIG. 3. FIG. 3 is a top view of the MTF-SC 200.

In the context of the present patent application, the term “monolithic thin-film solar cell” or “MTF-SC” means a photovoltaic device that consists of a plurality of electrically connected photovoltaic cells manufactured in a single manufacturing process. In other words, the monolithic device of the invention produces an output voltage Vₒᵤₜ of about 100 V or higher, which may be referred to as “gigantic” as compared to similar devices of the prior art. This gigantic output voltage is achieved by means of a single monolithic thin-film photovoltaic device of the invention manufactured on a transparent common substrate in a single process with a plurality of thin-film functional layers that are interconnected in a unique and specific way.

More specifically, the MTF-SC 200 comprises a plurality of individual tandem solar cells (hereinafter referred to as “individual TSCs”) 202a, 202b, . . . 202n, where the TSCs 202a and 202n are terminal TSCs, which, though generally are the same as the intermediate TSCs of the type designated by reference numeral TSC 202b, have some minor specific differences described below.

The individual TSCs 202a, 202b, . . . 202n (FIGS. 2 and 3) are arranged side by side in a longitudinal direction of a transparent common substrate 204 (FIG. 2) on which the individual TSCs 202a, 202b, . . . 202n are formed. The longitudinal direction of the transparent common substrate 204 coincides with the direction of the line of section II-II in FIG. 3. The invention allows generating a significantly enhanced output photo voltage Vₒᵤₜ, whereby an MTF-SC can be used as a photovoltaic generator.

In FIG. 2, reference numeral 205 designates a light-receiving surface of the MTF-SC 200 that receives solar radiation, shown by curves arrows L, through a transparent substrate 204. The transparent common substrate 204 comprises a glass plate or a flexible plastic material, such as vinyl. The transparent common substrate 204 may be pre-coated with an anti-reflection (AR) index-matching film(s) 206 made, e.g., from silicon dioxide, silicon nitride, or both.

Also, as shown in FIG. 2 by reference numeral 208, for reducing light reflection and improving light-trapping efficiency of the device, the surface of the transparent common substrate 204 may be pre-textured, as commonly done in known PV devices. The side 203, which is opposite the transparent common substrate 204 and hereinafter referred to as the “backside” of the MTF-SC 200, contains all electrical connections, as described below. Such an arrangement prevents shadowing the light-receiving surface 205 of the MTF-SC 200 with such elements as metal contacts, lines, etc. Thus, the maximum amount of incident light L1 can be used. It can also be seen from FIG. 2 that the back side is planar, which is convenient for forming on it various elements of the device.

Since all individual TSCs 202a, 202b, . . . 202n are identical, except for minor layout distinctions of the terminal TSCs, the following detailed description of the individual TSCs will relate only to an intermediate TSC 202b. It is understood that a plurality (n-2, where “n” is the total number of TSCs) of such intermediate TSCs 202b constitutes the main part of the MTF-SC 200 and determines the output characteristics of the device as a whole.

The individual TSC 202b consists of a pair of thin-film photovoltaic cells (hereinafter referred to as “PV cells”) arranged side-by-side on the transparent common substrate 204 in the longitudinal direction of the substrate. These PV cells, which comprise a first thin-film photovoltaic cell 202b1 and a second photovoltaic cell 202b2, will be further referred to as “a first PV cell 202b1” and a “second PV cell 202b2”, respectively. Each PV cell has a PIN structure, is formed laterally on the transparent common substrate 204 next to the adjacent PV cell, and is connected to the adjacent PV cell of the same TSC in series through the tunnel junction 210 that is formed between a portion 212 of the N-layer 214 of the first PV cell 202b1, which extends into the second PV cell 202b2, and a P-layer 216 of the second PV cell 202b2.

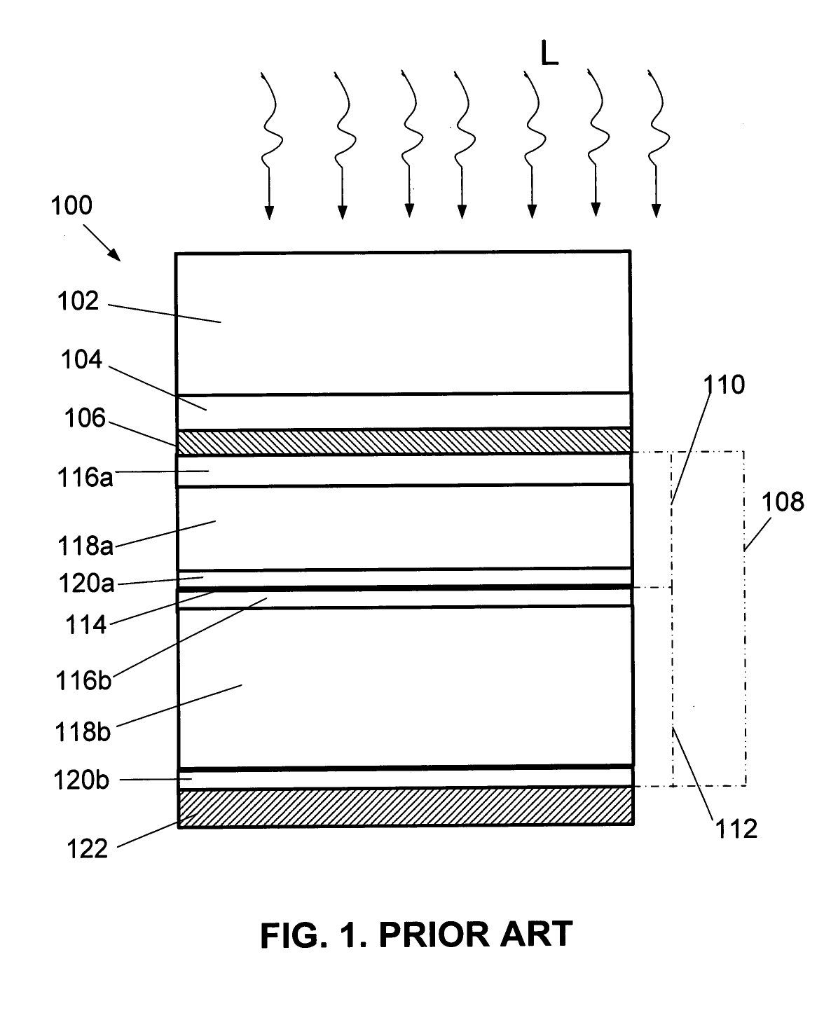

Similar to the known tandem solar cell shown in FIG. 1, each PV cell included in each individual TSC consists of a P-layer, an I-layer, and an N-layer. More specifically, as shown in FIG. 2, the first PV cell 202b1 contains a P-layer 203b1, an I-layer 205b1, and the aforementioned N-layer 214. On the other hand, the second PV cell 202b2 contains the aforementioned P-layer 216, an I-layer 205b2, and an N-layer 217.

As known in the art, the P-layers, N-layers, and I layers can be made of materials such as hydrogenated amorphous silicon (αSi:H), microcrystalline or nanocrystalline hydrogenated silicon (μc-Si:H and nc-Si:H, respectively), copper-indium-selenium (CIS), and copper-indium-gallium-selenium (CIGS), etc.

It can be seen from FIG. 2 that according to the invention the heavily doped P-layer 203b1 of the first PV cell 202b1 (which is one of the thin-film photovoltaic cells of the pair) is arranged substantially coplanar to the heavily doped N-layer 217 of the second PV cell 202b2 of the pair and that one of the heavily doped layers of the first thin-film photovoltaic cell (which in FIG. 2 is the heavily doped N-layer 214) has a portion 212 that extends under the heavily doped P-layer 216 of the second PV cell 202b2, thus forming overlapped layers. Thus, when one of the overlapped layers is a heavily doped P-layer, the other one is a heavily doped N-layer. The overlapped layers form an area of the tunnel junction 210 through which the first thin-film photovoltaic cell and a second thin-film photovoltaic cell are electrically connected to each other in series.

The aforementioned first PV cell 202b1 and the second PV cell 202b2 of the individual TSC 202b are isolated from each other by an insulating layer 218 formed over the entire interface between the cells except for the portion 212. Furthermore, the insulating layer 218 has shoulders that overlap a part of the back side 203, which makes it possible to isolate the first and second PV cells from each other except for the area of the tunnel junction 210.

According to one or more aspects of the present invention, individual TSCs 202a, 202b, . . . 202n of the MTF-SC 200 are reliably separated and isolated from each other by narrow deep through trenches, such as through trenches 220a and 220b. Although the number of such trenches will be (n-1), where “n” is the number of the individual TSCs in the entire device, only two trenches are shown in FIG. 2. The through trenches are formed vertically between the surface of the AR film 206 and the back side 203 of the MTF-SC 200.

According to the present invention, the aforementioned deep trenches can be filled with an electrically insulating material, such as silicon oxide, silicon nitride, or the like, which forms insulating layers 222a and 222b that provide reliable electrical isolation of the adjacent TSCs. The same insulating layers have shoulders that overlap a part of the backside 203 adjacent to the trenches, which makes possible a reliable interconnection between the individual TSCs. Deep trenches 220a and 220b and insulating layers 222a and 222b described above are made by the well known patterning processes such as photo lithography, etching, and CVD deposition.

The first PV cell and the second PV cell of each individual TSC each has a conductive electrode formed on the P-layer of the first PV cell and on the N-layer of the second PV cell. The TSC 202b, which is considered the example of all other similar TSCs, contains a first electrode 224b1 formed on the P-layer 203b1 of the first PV cell 202b1 and a second electrode 224b2 formed on the N-layer 217 of the second PV cell 202b2, and so on. In order to provide conditions for maximal back reflection of the incident light from the back side 203, the electrodes, such as electrodes 224b1 and 224b2, should be large enough to cover the largest possible area of the PV cell. Moreover, since a combination of the electrodes, such as the electrodes 224b1 and 224b2 having high reflective properties, with the pre-textured surface of the common substrate 208 provides good light-trapping conditions. Therefore, the I layers, such as I layers 205b1 and 205b2 of the PV cells, can be made thin for reducing the negative impact from the Staebler-Wronsky effect.

To connect the sequentially arranged individual TSCs in series and thus to provide an enhanced output voltage Vₒᵤₜ, each individual TSC is connected to the adjacent one by means of a conductive link. Thus, the TSC 202a is connected to the TSC 202b by a conductive link 226a (FIGS. 2 and 3). Other conductive links are designated by reference numerals 226b, 226ₙ₋₁. The individual TSC 202b is connected to the next adjacent TSC 202c (only a part of which is shown in FIGS. 2 and 3), and so on. Thus each conductive link connects the second PV cell of an individual TSC with the first PV cell of the next adjacent TSC, except for the terminal TSCs 202a and 202n, which are used as output terminals of the MTF-SC 200. In particular, the conductive electrode 224a1 is connected to an output lead 228a, while the conductive electrode 224n2 is connected to an output lead 228n. In order to make room for output contacts, the conductive electrode 224a1 of the first PV cell 202a1 of the terminal TSC 202a and the conductive electrode 224n2 of the second PV cell 202n2 of the terminal TSC 202n are made slightly larger than the respective electrodes of the intermediate TSCs.

Each cell of the pair has a lateral dimension in the longitudinal direction L of the transparent common substrate 204 and a thickness in the direction perpendicular to the longitudinal direction L of the transparent common substrate 204.

According to the invention, dimensions of the first and second PV cells are chosen to make thicknesses of the photoactive intrinsic I-layers and cross-sectional areas of first and second PV cells equal or nearly equal to each other thus providing equal or nearly equal photo currents generated in the cells of each individual TSC. This ensures perfect current matching conditions in all individual TSCs. Furthermore, to reduce radiation and photo current losses in the trench region, the deep trenches are made as narrow as possible when compared to the areas of the PV cells.

If necessary, the entire MTF-SC 200 can be isolated over its external periphery with a passivation medium 230 so that the entire device can be isolated from another similar MTF-SC supported by the same common substrate.

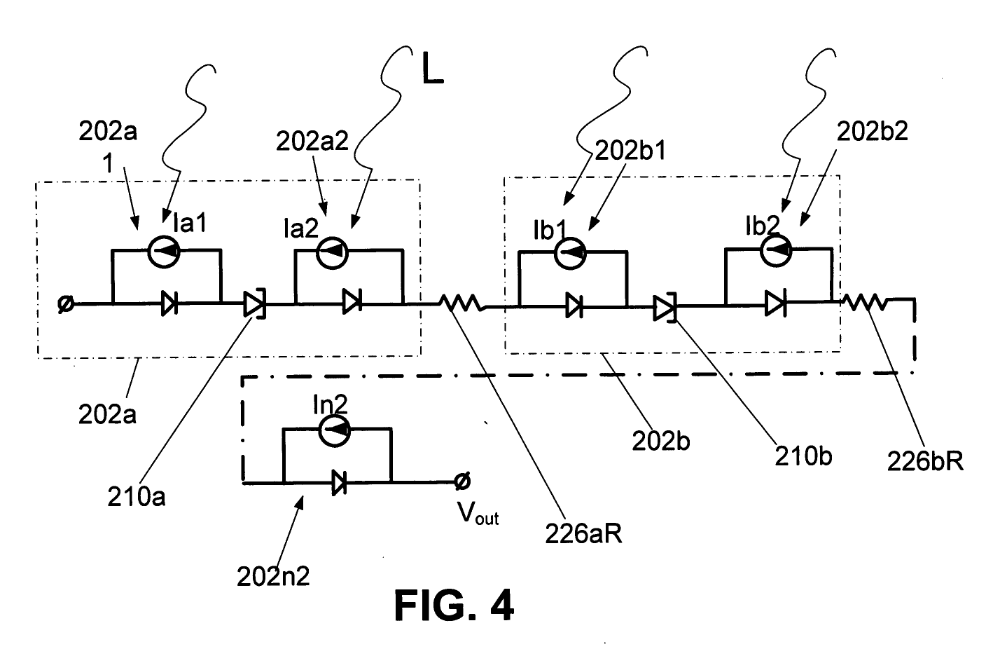

In order to understand how the MTF-SC 200 operates, let us consider an equivalent electrical circuit of the MTF-SC 200, which is shown in FIG. 4. Components of the MTF-SC 200 shown in FIGS. 2 and 3, are designated in FIG. 4 by the same reference numerals as in the aforementioned drawings. Thus, the MTF-SC 200 consists of a plurality of individual TSCs 202a, 202b, . . . 202n, where 202n2 designates the second PV cell of the terminal TSC 202n. In the equivalent circuit of FIG. 4 the components of the PV cells are shown by standard schematic symbols generally used in circuit diagrams of solar cells. In particular, reference numerals 210a, 210b, etc., designate tunnel diodes. However, in FIG. 4 the conductive links 226a, 226b, etc., are shown in FIG. 4 as equivalent resistors 226aR and 226bR, etc.

The MTF-SC 200 (FIGS. 2 and 3) operates as follows. The incident light L passes through the transparent substrate, falls onto the light-receiving surface 205, and is partially absorbed in each individual TSC, such as the individual TSC 202b. In particular, the light L1 is absorbed in the first PV cell 202b1 and the second PV cell 202b2 of each individual TSC. A major part of the incident light L1 is absorbed in the I-layer 205b1 of the first PV cell 202b1 and the I-layer 205b2 of the second PV cell 202b2 (although description of the MTF-SC operation is described with reference to only one individual TSC 202b, it is understood that the same processes occur in each individual TSC within the plurality of TSCs contained in the MTF-SC 200). It is further understood that only the photoactive part of the light L1 is absorbed in the PV cells, and that the back reflection of the light L1 from the conductive electrodes, such as 224b1 and 224b2 on the back side 203, provides an additional absorption of the reflected light.

As known in the art, in response to the light radiation, both PV cells 202b1 and 202b2 generate photocurrent (shown in FIG. 4 for the cells 202b1 and 202b2 as current Ib1 and current Ib2, respectively).

Since the I-layers of the first and the second PV cells of each individual TSC can be made practically equal in thickness and lateral dimensions, the amount of absorbed light and the photo currents Ib1 and Ib2 (FIG. 4) are practically equal as well, and this, in turn, provides perfect current matching conditions for the PV cells of each individual TSC. It should be also noted that PIN structures of both PV cells can be manufacture in a similar process whereby the functional layers of the PV cells will acquire practically the same properties. This further contributes to providing generation of equal currents in similar layers of the PV cells.

Since the I-layers, such as 205b1 and 205b2 of the first and second PV cells, respectively, are electrically isolated from each other, the only electrical connection between these PV cells is a series connection provided by the tunnel junction 210. Due to this series connection, the photocurrent through the entire structure of an individual TSC is constant and equal to Ib1 (as mentioned above, Ib1 is equal to Ib2), and the photo voltage generated in each individual TSC (i.e., the voltage between the conductive electrodes 224b2 and 224b1 of FIGS. 2 and 3) is the sum of photo voltages generated in each PV cell. It is understood that in order to simplify the description, other electrical elements of the PV cells, such as tunnel junction equivalent resistances, shunt resistances, contact resistances, etc. are not shown since they are insignificant for the invention, and therefore their description with reference to the equivalent circuit of FIG. 4 is omitted as well.

The above description relates to the operation of only one individual TSC 202b, but it is understood that the same processes occur in each individual TSC of the entire MTF-SC 200 of the invention. In other words, all individual TSCs of the MTF-SC 200 will generate the same photocurrent and the same photo voltage. Consequently, due to the series connection of individual TSCs provided by the links 226a, 226b, and so on, the total photo voltage Vₒᵤₜ (FIG. 4) generated between the terminals 228b and 228a is close to the sum of all individual photovoltages of each individual TSC. For instance, if each individual TSC generates 1.5V and the number “n” of individual TSCs is equal to 100 (n=100), then in the ideal case the Vₒᵤₜ should be equal to 150V, but in view of electric potential losses in the resistors 226a, 226b, etc. (FIG. 4), the actual Vₒᵤₜ may be about 100V, or greater, which, anyway is a very high value practically unachievable with any conventional monolithic solar cell.

Thus, by choosing at the design stage the appropriate thickness of I-layers, lateral dimensions of PV cells of each individual TSC, number of individual TSCs in the MTF-SC, etc., given output currents and voltages, including gigantic values of Vₒᵤₜ, can be achieved.

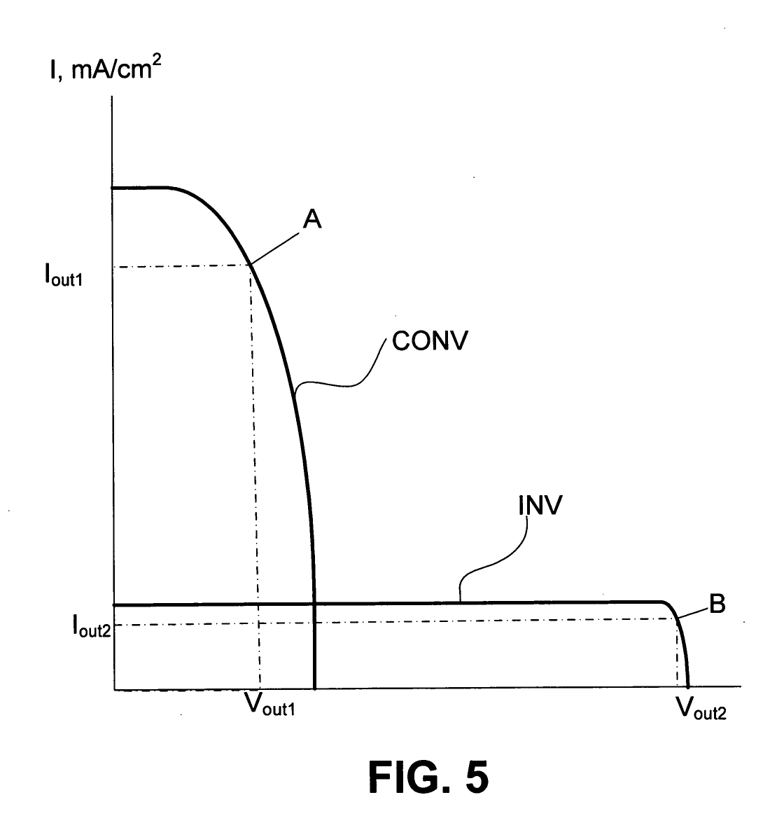

FIG. 5 is a graph that compares output I-V characteristics of the device of the invention with a conventional thin-film tandem solar cell. In this graph the curve INV shows an I-V characteristics of the MTF-SC of the invention which consists of 10 individual TSCs of the type described above, and the curve CONV shows I-V characteristics of a conventional two junction thin-film TSC. The points B and A designate coordinates that correspond to the maximal output power of the MTF-SC (Iₒᵤₜ₂; Vₒᵤₜ₂) of the invention and of the conventional two junction thin-film TSC (Iₒᵤₜ₁; Vₒᵤₜ₁), respectively. As shown, at approximately the same output power, the output voltage Vₒᵤₜ₂ of the MTF-SC of the invention is significantly higher than the output voltage Vₒᵤₜ₁ of the conventional device. For example, a typical value of Vₒᵤₜ₁ is about 1.6 V, while in the case of the device of the invention consisting, e.g., of 10 individual TSCs a typical value of Vₒᵤₜ is in the range of 13 to 14 V.

Thus, the present invention provides a novel and efficient Monolithic Thin-Film Solar Cell (MTF-SC) that is capable of generating a significantly enhanced output photovoltage Voc and therefore may functions also as a photovoltaic generator.

Although the invention has been shown and described with reference to specific embodiments, it is understood that these embodiments should not be construed as limiting the areas of application of the invention and that any changes and modifications are possible provided that these changes and modifications do not depart from the scope of the attached patent claims. For example, the invention allows incorporation of any number of individual TSCs into the structure of the MTF-SC. The only limitation in selecting the number of the individual TSCs is the technological capability of the microelectronic processes, which, nevertheless, allow integration of thousands of the elements. Furthermore, although the structure of FIG. 2 shows a predetermined sequence of the layers in the PIN structures of the PV cells 105 and 110, these sequences may be inversed. For example, the combination of PIN-TJ-PIN can become the combination of NIP-TJ-NIP.

1. A monolithic thin-film photovoltaic device with enhanced output voltage comprising:
a transparent common substrate having a light-receiving surface and a longitudinal direction parallel to the light-receiving surface;
at least one individual tandem solar cell comprising a pair of thin-film photovoltaic cells arranged side-by-side on the transparent common substrate in the longitudinal direction of the transparent common substrate, the cells comprising a first thin-film photovoltaic cell and a second thin-film photovoltaic cell, each cell of the pair comprising a heavily doped P-layer, and a heavily doped N-layer, and an intrinsic I-layer therebetween, each cell of the pair having a lateral dimension in the longitudinal direction of the transparent common substrate and a thickness in the direction perpendicular to the longitudinal direction of the transparent common substrate, wherein the heavily doped P-layer of one of the thin-film photovoltaic cells is arranged substantially coplanar to the heavily doped N-layer of another of the cells, one of the heavily doped layers of the first thin-film photovoltaic cell extending under the heavily doped layer of the second thin-film photovoltaic cell thus forming overlapped layers, wherein when one of the overlapped layers is a heavily doped P-layer, the other one is a heavily doped N-layer and wherein the overlapped layers form an area of a tunnel junction through which the first thin-film photovoltaic cell and a second thin-film photovoltaic cell are electrically connected to each other in series.

2. The monolithic thin-film photovoltaic device according to claim 1, further comprising an insulating layer formed between the first thin-film photovoltaic cell and the second thin-film photovoltaic cell except in the area of the tunnel junction.

3. The monolithic thin-film photovoltaic device according to claim 2, further comprising a planar back side on the side of the device opposite to the light-receiving surface.

4. The monolithic thin-film photovoltaic device according to claim 3, further comprising a first conductive electrode formed on the heavily doped layer of the first thin-film photovoltaic cell located on the back side of the device and a second electrode formed on the heavily doped layer of the second thin-film photovoltaic cell located on the back side of the device.

5. The monolithic thin-film photovoltaic device of claim 1, comprising a first terminal individual tandem solar cell, a second terminal individual tandem solar cell, and a plurality of the individual tandem solar cells arranged on the transparent common substrate side-by-side to each other in the longitudinal direction of the common substrate between the a first terminal individual tandem solar cell and the second terminal individual tandem solar cell, the device further comprising a conductive link between the first electrode of the first thin-film photovoltaic cell of each individual tandem solar cell and the second electrode of the second thin-film photovoltaic cell of the preceding individual tandem solar cell, except for the first terminal individual tandem solar cell and the second terminal individual tandem solar cell.

6. The monolithic thin-film photovoltaic device of claim 5, further comprising through trenches between the adjacent individual tandem solar cells, said through trenches being formed under the conductive links and extending from the back side of the device to the transparent common substrate.

7. The monolithic thin-film photovoltaic device of claim 6, wherein the through trenches are filled with an electrically insulating material.

8. The monolithic thin-film photovoltaic device of claim 4, comprising a first terminal individual tandem solar cell, a second terminal individual tandem solar cell, and a plurality of the individual tandem solar cells arranged on the transparent common substrate side-by-side to each other in the longitudinal direction of the common substrate between the a first terminal individual tandem solar cell and a second terminal individual tandem solar cell, the device further comprising a conductive link between the first electrode of the first thin-film photovoltaic cell of each individual tandem solar cell and the second electrode of the second thin-film photovoltaic cell of the preceding individual tandem solar cell, except for the first terminal individual tandem solar cell and the second terminal individual tandem solar cell.

9. The monolithic thin-film photovoltaic device of claim 8, further comprising through trenches between the adjacent individual tandem solar cells, said through trenches being formed under the conductive links and extending from the back side of the device to the transparent common substrate.

10. The monolithic thin-film photovoltaic device of claim 9, wherein the through trenches are filled with an electrically insulating material.

11. The monolithic thin-film photovoltaic device of claim 1, wherein the lateral dimensions and the thickness of the first thin-film photovoltaic cell are substantially equal to the lateral dimensions and the thickness of the second thin-film photovoltaic cell.

12. The monolithic thin-film photovoltaic device of claim 4, wherein the lateral dimensions and the thickness of the first thin-film photovoltaic cell are substantially equal to the lateral dimensions and the thickness of the second thin-film photovoltaic cell.

13. The monolithic thin-film photovoltaic device of claim 9, wherein the lateral dimensions and the thickness of the first thin-film photovoltaic cell are substantially equal to the lateral dimensions and the thickness of the second thin-film photovoltaic cell.

14. The monolithic thin-film photovoltaic device of claim 1, wherein the P-layer, I-layer, and N-layer are made from materials selected from the group consisting of hydrogenated amorphous silicon, microcrystalline or nanocrystalline hydrogenated silicon, copper-indium-selenium, and copper-indium-gallium-selenium.

15. A monolithic thin-film photovoltaic device, comprising:
a transparent common substrate having a light-receiving surface and a longitudinal direction parallel to the light-receiving surface;
a first terminal individual tandem solar cell;
a second terminal individual tandem solar cell; and
a plurality of individual tandem solar cells arranged on the transparent common substrate side-by-side to each other in the longitudinal direction of the common substrate between the a first terminal individual tandem solar cell and the second terminal individual tandem solar cell,
each individual tandem solar cell comprising a pair of thin-film photovoltaic cells arranged side-by-side on the transparent common substrate in the longitudinal direction of the transparent common substrate, each thin-film photovoltaic cell comprising a first thin-film photovoltaic cell and a second thin-film photovoltaic cell having a heavily doped P-layer, a heavily doped N-layer, and an intrinsic Mayer therebetween;
each thin-film photovoltaic cell having a lateral dimension in the longitudinal direction of the transparent common substrate and a thickness in the direction perpendicular to the longitudinal direction of the transparent common substrate, wherein the heavily doped P-layer of one of the thin-film photovoltaic cells is arranged substantially coplanar to the heavily doped N-layer of another of the thin-film photovoltaic cells of the pair;
one of the heavily doped layers of the first thin-film photovoltaic cell of the pair extending under the heavily doped layer of the second thin-film photovoltaic cell of the pair thus forming overlapped layers, wherein when one of the overlapped layers is a heavily doped P-layer, the other one is a heavily doped N-layer and wherein the overlapped layers form an area of a tunnel junction through which the first thin-film photovoltaic cell and a second thin-film photovoltaic cell are electrically connected to each other.

16. The monolithic thin-film photovoltaic device according to claim 15, further comprising an insulating layer formed between the first thin-film photovoltaic cell and the second thin-film photovoltaic cell of the pair, except in the area of the tunnel junction.

17. The monolithic thin-film photovoltaic device according to claim 16, further comprising:
a planar back side on the side of the device opposite to the light-receiving surface;
a first conductive electrode formed on the heavily doped layer of the first thin-film photovoltaic cell of the pair located on the back side of the device and a second electrode of the pair formed on the heavily doped layer of the second thin-film photovoltaic cell of the pair located on the back side of the device.

18. The monolithic thin-film photovoltaic device of claim 15, further comprising a conductive link between the first electrode of the first thin-film photovoltaic cell of each individual tandem solar cell and the second electrode of the second thin-film photovoltaic cell of the preceding individual tandem solar cell, except for the first terminal individual tandem solar cell and the second terminal individual tandem solar cell.

19. The monolithic thin-film photovoltaic device of claim 18, further comprising through trenches between the adjacent individual tandem solar cells, said through trenches being formed under the conductive links and extending from the back side of the device to the transparent common substrate.

20. The monolithic thin-film photovoltaic device of claim 19, wherein the through trenches are filled with an electrically insulating material.

21. The monolithic thin-film photovoltaic device of claim 15, wherein the lateral dimensions and the thickness of the first thin-film photovoltaic cell are substantially equal to the lateral dimensions and the thickness of the second thin-film photovoltaic cell.

22. The monolithic thin-film photovoltaic device of claim 21, wherein the lateral dimensions and the thickness of the first thin-film photovoltaic cell are substantially equal to the lateral dimensions and the thickness of the second thin-film photovoltaic cell.

23. The monolithic thin-film photovoltaic device of claim 15, wherein the P-layer, I-layer, and N-layer are made from materials selected from the group consisting of hydrogenated amorphous silicon, microcrystalline or nanocrystalline hydrogenated silicon, copper-indium-selenium, and copper-indium-gallium-selenium.
